(19) United States
(12) Patent Application Publication
(10) Pub. No.: US 2025/0202190 A1
(43) Pub. Date: Jun. 19, 2025

(54) STACKED LASER ASSEMBLY AND METHOD FOR CREATING SAME

(71) Applicant: ams-OSRAM International GmbH, Regensburg (DE)

(72) Inventors: Nicole BERNER, Walderbach (DE); Erik HEINEMANN, Regensburg (DE); Markus RICHTER, Burglengenfeld (DE); Andreas ROZYNSKI, Regensburg (DE)

(73) Assignee: ams-OSRAM International GmbH, Regensburg (DE)

(21) Appl. No.: 18/848,669

(22) PCT Filed: Mar. 24, 2023
(86) PCT No.: PCT/EP2023/057694

§ 371 Date: Sep. 19, 2024

(30) Foreign Application Priority Data
Mar. 24, 2022 (DE) 10 2022 106 937.0

(51) Int. Cl. H01S 5/02345; H01S 5/0236; H01S 5/40

(52) U.S. Cl. CPC H01S 5/02345; H01S 5/0236; H01S 5/4043

(57) ABSTRACT

The invention relates to a stacked laser arrangement with a first laser device with a light-emitting side and a semiconductor body forming a resonator with an active zone and with two main sides and side surfaces arranged essentially perpendicularly thereto, the side surfaces comprising an insulating material. In addition, at least one second laser device with a light-emitting side and a semiconductor body forming a resonator with an active zone and with two main sides and side surfaces arranged substantially perpendicular thereto is provided, the side surfaces comprising an insulating material. The light exit sides of the first laser device and at least one second laser device point in the same direction and the at least one second laser device is arranged on one of the main sides of the first laser device. According to the invention, electrical contact is made to the active zone of the first and at least one second laser device via at least one of their respective side surfaces, in that the insulating material is perforated in places.

### CROSS-REFERENCE TO RELATED APPLICATIONS

The present application is a national stage entry from International Application No. PCT/EP2023/057694, filed on Mar. 24, 2023, published as International Publication No. WO 2023/180550 A1 on Sep. 28, 2023, and claims the priority of the German first application DE 10 2022 106 937.0 filed Mar. 24, 2022, the disclosures of all of which are hereby incorporated by reference in their entireties.

### FIELD

The present invention relates to a stacked laser arrangement and a method for generating such a laser array.

### BACKGROUND

For various applications, including virtual reality or augmented reality, laser diodes are used to generate visual information, the light from which is guided to the user's eye via suitable optics. Various laser diodes are used for the red, green and blue color range by placing them on a corresponding carrier and, if necessary, aligning them precisely with the optics.

The conventional manufacturing techniques required for this are often complex and expensive. In addition, the laser diodes arranged on a circuit board require complex optics in order to display the different colors correctly on the user's lens. Although these so-called squint angles can be compensated for by suitable lenses, they are often larger. This is particularly the case if the optics are located outside the package, as the laser beams first expand to the optics. This increases the size, which is undesirable for smaller applications, e.g. for spectacles.

There is therefore a need to find a space-saving solution for laser arrangements, especially for the virtual reality or augmented reality sector, which can also be implemented cost-effectively.

### SUMMARY OF THE INVENTION

This need is met by the objects of the independent patent claims. Further developments and embodiments of the proposed principle are given in the sub-claims.

The inventors propose stacking several laser devices on top of each other along one of their main sides in order to reduce the space required. These can then be contacted by various means, whereby on the one hand the different resonator lengths can be utilized. On the other hand, neighboring laser devices can also be connected to a common potential so that common contacting for the individual laser devices is possible in a simple manner. Stacking the laser device results in a particularly space-saving design, as the finished stack can be used as a single module. A further submount can therefore be omitted. In addition, various stacked devices can be produced in this way, i.e. laser devices with individual laser combs (single ridges) but also with several laser combs (multi-ridges). Depending on the desired light output power, the number of stacked laser arrangements of individual colors can be varied.

The relative position of the individual laser devices to each other is determined by the stacking. In particular, precise positioning in relation to each other is possible so that, on the one hand, the side surfaces of the devices are aligned flush with each other and, on the other hand, simpler lenses can be used for the optical path. It is possible to stack both individual laser devices and groups of devices up to wafer stacking. This enables the use of parallel processes in production. The resulting stacks require fewer assembly steps and only one burn-in process for the entire stack, so that further advantages can be realized.

Furthermore, some aspects take advantage of the fact that the side surfaces are exposed during production of the individual laser devices. These allow contact to be made with electrically conductive areas that lead to the active zone of the respective laser device.

Accordingly, in one possible embodiment, a stacked laser arrangement comprises a first and at least one second laser device. The first and at least one second laser device each comprise a resonator-forming semiconductor body with an active zone. This has a light-emitting side. Each of the laser devices has two main sides and two side surfaces extending perpendicularly thereto. The side surfaces of the two laser devices each have an insulating material. In this context, the term “main sides” refers to the sides of the laser device that extend essentially in the direction of growth of the semiconductor body. The light-emitting surface is essentially perpendicular to the main sides. In some embodiments, the laser comb extends parallel to the main side and is not necessarily centered on the light-emitting surface, but is offset from the center in the direction of one of the main sides.

The light emitted by the laser devices also has a non-rotationally symmetrical beam profile with a fast axis and a slow axis perpendicular to the fast axis. The beam profile is elliptical, with the large semi-axis, also known as the fast axis, running parallel to the side surfaces and the small or slow axis aligned parallel to the main sides.

According to the proposed principle, the light-emitting sides of the first laser device and of the at least one second laser device point in the same direction. In addition, the at least one second laser device is arranged on one of the main sides of the first laser device and is attached thereto. Conveniently, the two laser devices are the same width so that the side surfaces are flush with each other.

This achieves a very small design with the smallest possible distance between the respective laser combs. Electrical contact to the active zones of the first and at least one second laser device is now not made via the main side, but via at least one of their respective side surfaces, in that the insulating material is perforated in places. This aspect makes it possible to achieve electrical contact independently of the stacking of the individual laser devices.

In this way, a very compact design of a stack of laser devices is achieved. In one embodiment, electrical contacts are applied to the insulating material of the side surfaces, for example in the form of metallic surfaces. These can be vapor-deposited or sputtered onto the insulating material. In one example, a first electrical contact can be arranged on a first side surface and a second electrical contact on the second (opposite) side surface. The contacts are electrically connected through the insulating material of the side surfaces to the electrically conductive areas on the inside. In another example, the first and second electrical contacts are arranged on a common side surface. In this case, the two contacts are laterally spaced apart in order to avoid a possible short circuit.

In some aspects, a metallic layer is arranged on the side surfaces, which forms the contact surface in each case. In order to achieve easier contacting along this side surface, it may be provided to optionally extend the metallic layer over at least 50% of a length of the side surface, possibly also over the entire length of the side surface. The electrically conductive areas within a laser device are vertically spaced from each other, the spacing being determined by the epitaxial growth process and the manufacturing steps. Accordingly, in some aspects, the apertures on the side surfaces that contact the electrically conductive areas of the laser devices are laterally offset from each other. For example, with respect to the light emitting side and with respect to one of the main sides, an aperture through the insulating material on one side surface may be vertically offset from an aperture through the insulating material on the other side surface. In some embodiments, the openings may be at the same height but on different sides, for example if the electrically conductive areas within the laser device lead to the active zone.

During the production of the individual laser devices, the main sides can be provided with a dielectric layer. As a result, the two laser devices are electrically insulated from each other after stacking. An adhesive or an additional electrically insulating material can also be provided between the laser devices, which is particularly advantageous if one of the laser devices has no additional dielectric layer or only a very thin layer. This creates a special space-saving design. The adhesive layer can be an epoxy. In another aspect, the bonding layer can be metallic. It also makes sense to choose a material for the bonding layer with particularly high heat transfer properties. This allows any heat generated during operation of the stacked laser arrangement to be dissipated easily. The contacts, webs on the side surfaces or the side surfaces themselves can also be used in this context.

A further aspect results from subsequent processing of a stack of laser devices. Thus, in some aspects, it may be provided that the contacting takes place via a conductive web extending at least partially along the side surface of the respective laser device. This web is arranged on the insulating material of the side surface and, in some aspects, also extends at least partially over a side surface of the respective other laser device. This allows longer conductive webs to be formed, which lead along the side surfaces of different laser devices up to the contact. In other words, a laser device is contacted via metallic contact webs running along the side surfaces.

In some aspects, a metallic layer is provided that extends along a plurality of side surfaces and contacts electrically conductive regions of the first and the at least one second laser device on the same side. As a result, the metallic layer forms a common connection surface so that in an electrical operation the laser devices are at the same potential.

In some examples, the stacked laser arrangement is designed to emit light of different wavelengths. For this purpose, in some embodiments, the first laser device has a resonator length that differs from one of the at least one second laser device. It is expedient to stack the laser devices in such a way that the laser device with the greatest resonator length is at the bottom in relation to a later assembly.

In a further aspect, the stacked laser arrangement comprises a carrier with a number of contact surfaces, in particular contact surfaces arranged in a row.

The carrier can be a PCB board or a mount to which the laser array is attached. In other words, the stack is attached to the carrier rotated by 90° in this way. This also aligns the fast axis parallel to the carrier during operation.

In one embodiment, according to the proposed principle, the first and at least one second laser device are attached to the carrier in such a way that the electrical contacting of the side surface of at least one of the first and at least one second laser device is arranged on the contact surfaces. In this way, direct electrical contact is achieved, for example using suitable solders. At the same time, these contact surfaces can improve the mechanical stability and serve to dissipate heat during operation. In order to compensate for any tolerances, the contact surfaces can be slightly larger than the corresponding contacts on the side surfaces. In this context, it is envisaged in some aspects that all contact surfaces are arranged on one side.

In another aspect, it is intended to attach the side surface to a common surface in order to use it for heat transport. In this way, electrical contact can also be made via the side surface facing away from the carrier, for example by means of bonding wires that lead to electrical contacts on the surface of the carrier.

In another aspect, the laser arrangement comprises a carrier having a number of contact surfaces, in particular contact surfaces arranged in a row; wherein a main side of the first or at least one second laser device is arranged facing the carrier and a conductive web along the side surface of the first or at least one second laser device is electrically conductively connected to one of the contact surfaces. The web thus leads along one or more side surfaces to the contact for the laser device. This allows a particularly economical design, since bonding wires are not necessary and the through-plating of the webs and the contact surfaces is created.

In addition, the stacked laser arrangement can also be arranged on the carrier in such a way that the main sides are arranged parallel to a surface. For example, a main side of the first or at least one second laser device can be arranged facing the carrier, with a contact surface on one of the side surfaces of the first or at least one second laser device being electrically conductively connected to one of the contact surfaces, for example via a bonding wire.

Another aspect relates to a method for generating a stacked laser arrangement. Among other things, a first laser device with a light-emitting side and a semiconductor body forming a resonator with an active zone is provided. Likewise, at least one second laser device with a light-emitting side and a semiconductor body forming a resonator with an active zone is provided. The first and the at least one second laser device each have two main sides and side surfaces arranged substantially perpendicularly thereto. The laser devices are thus designed as already described above.

For example, they are produced epitaxially on a growth substrate and then separated. The manufacturing process is designed in such a way that the side surfaces of the respective laser devices have at least one electrically conductive area that makes electrical contact with the active zone.

The first and at least one second laser device are aligned with each other, for example stacked on top of each other. The tolerances can be as low as possible. After alignment, they are attached to each other so that a stack is formed that has flush side surfaces. Depending on the design, this can be done using an electrically insulating material, in particular an adhesive.

Then, at least one of the electrically conductive regions of the first and at least one second laser device is electrically contacted via at least one of their respective side surfaces, wherein an insulating material which is perforated in the region of the contacting is applied to the side surfaces. In some aspects, an electrically insulating layer is applied to the side surfaces for this purpose and then structured. Furthermore, an aperture is created in the electrically insulating layer so that the at least one electrically conductive region is exposed. An electrically conductive material is filled into this opening and the electrically conductive area is thus contacted. An electrical contact is then formed on the side surface. In this way, contact is made via the side surfaces, creating a space-saving arrangement.

There are several options for contacting the electrically conductive areas and connecting them to contacts on a carrier. In one aspect, an electrically conductive web is formed as a contact on the side surface. The electrically conductive web can extend along the length of the side surface, e.g. of the resonator. However, it is also possible to form the web substantially vertically, i.e. over the side surfaces of the stack. In some aspects, it is conceivable to provide the web as a metallic layer extending at least partially over the side surface of a plurality of webs. The metallic layer can serve as a contact when the stacked laser arrangement is placed on a carrier.

In another aspect, the electrical contact is created by forming a sequence of layers with an insulating material. One or more openings can be made in the layer sequence, for example by etching, laser drilling or similar. The openings are filled with an electrically conductive material. The layer sequence can be created separately and only connected to the stacked laser arrangements in a subsequent step. A metallic layer can also be deposited on the layer sequence, which contacts the electrically conductive material and thus serves as a contact.

In a further aspect, the layer sequence is now attached to the side surfaces of the first and at least one second laser device so that the apertures are in contact with the electrically conductive areas. In this way, the electrically conductive areas are guided outwards onto the side surfaces.

Some other items concerning various aspects of stacked laser arrangements are listed in the following non-exhaustive list:
1. Stacked laser arrangement, comprising:
   a first laser device having a light-emitting side and a semiconductor body forming a resonator with an active zone and with two main sides, and with an electrical contact on each of the two main sides;
   at least one second laser device with a light-emitting side and a semiconductor body forming a resonator with an active zone and with two main sides and with an electrical contact on each of the two main sides;
whereby
   a composite member having a dielectric material disposed between the first and at least one second laser device; the composite member comprising a conductive layer on a major side contacting the electrical contact of the first laser device and having an exposed contact area; wherein
   an electrical contact of the at least one second laser device facing the composite element is exposed; and a length of the first laser device is shorter than a length of the at least one second laser device.
2. Stacked laser arrangement according to item 1; wherein the composite element comprises a ceramic having a surface metallization as a conductive layer.
3. Stacked laser arrangement according to item 1 or 2; further comprising a carrier with a conductive contact area which is electrically and optionally mechanically connected to the electrical contact of the at least one second laser device facing away from the composite element and contacts the exposed contact area.
4. Stacked laser arrangement according to any of items 1 to 3; wherein the exposed contact area and the electrical contact facing the composite element are arranged side by side.
5. Stacked laser arrangement according to any of items 1 to 4, wherein the first laser device is designed to generate light of a first wavelength and the at least one second laser device is designed to generate light of a second wavelength.
6. Stacked laser arrangement according to any of items 1 to 5, wherein at least one of the electrical contacts on the two main sides of at least one of the laser devices extends along the length of the main side of the laser device.
7. Stacked laser arrangement according to item 2, in which the carrier has further contact areas which are connected via bonding wires to the exposed contact area and to the electrical contact facing the composite element
8. Stacked laser arrangement according to any one of items 1 to 6, further comprising an electrically insulated extending web extending along the side surface of the at least one second laser device and contacting the exposed contact surface of the composite element or the electrical contact facing the composite element.
9. Stacked laser arrangement according to any of items 1 to 9, wherein the exposed contact surface and/or the electrical contacts are located at an end of the laser devices remote from the light-emitting side.
10. Stacked laser arrangement, comprising:
   a first laser device with a light-emitting side and a semiconductor body forming a resonator with an active zone and with two main sides;
   at least one second laser device with a light-emitting side and a semiconductor body forming a resonator with an active zone and with two main sides;
   wherein the first laser device is arranged on the at least one second laser device; wherein
   the at least one second laser device has at least two conductive feedthroughs; and
   the first laser device has at least one conductive feedthrough, which is arranged above one of the at least two feedthroughs and makes electrical contact with it.
11. Stacked laser arrangement according to item 10, wherein a first one of the at least two conductive feedthroughs contacts a contact on a main side of the first laser device facing the at least one second laser device; and/or the second one of the at least two conductive feedthroughs contacts the at least one conductive feedthrough of the first laser device.
12. Stacked laser arrangement according to item 10 or 11, in which the at least one conductive feedthrough leads from a first main side to an opposite main side and is connected there to a contact.
13. Stacked laser arrangement according to item 11 or 12, wherein the contact comprises a planar metallic layer optionally extending along a side length of the laser device.
14. Stacked laser arrangement according to any one of items 10 to 13, wherein a dielectric layer adhesive layer is provided between the first and the at least one second laser device.
15. Stacked laser arrangement according to any one of items 10 to 14, further comprising a carrier having a plurality of contact pads spaced to contact the at least two conductive feedthroughs.
15. Stacked laser arrangement according to any one of items 10 to 14, in which the feedthrough comprises a dielectric material covering the edge of the feedthrough with an internal conductive core, in particular of metal.

The individual laser devices of the stacked laser arrangements described here can of course be combined with each other. In this respect, it is possible to form a stacked laser arrangement that has laser devices with contacts on the side surfaces as well as on the main surfaces.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a schematic sectional view of a laser device according to some aspects of the proposed principle;

FIG. 2 shows a schematic view of the light-emitting surfaces of a stacked laser arrangement according to some aspects of the proposed principle;

FIG. 3 shows an embodiment of a stacked laser arrangement mounted on a carrier according to some embodiments of the proposed principle;

FIGS. 4A to 4D are representations of the stacked laser arrangement as seen from the light-emitting surfaces in a side view and in a top view according to some aspects of the proposed principle;

FIG. 5 shows a further embodiment of a stacked laser arrangement with some aspects of the proposed principle

FIG. 6A to 6C is an illustration of the design in FIG. 5 from different perspectives;

FIG. 7 shows a view of the stacked laser arrangement mounted on a carrier in a rotated state;

FIGS. 8A and 8B show a further embodiment of a stacked laser arrangement according to some aspects of the proposed principle on a carrier;

FIG. 9 shows a further embodiment of a stacked laser arrangement according to some aspects of the proposed principle on a carrier;

FIG. 10 is a further illustration of a stacked laser arrangement with some aspects of the proposed principle;

FIG. 11 shows the first steps of a method for generating a stacked laser arrangement according to some aspects of the proposed principle;

FIG. 12 shows a further step of the method for generating a stacked laser arrangement according to some aspects of the proposed principle;

FIG. 13 is an embodiment for attachment by self-adhesive side surfaces to create a stacked laser arrangement according to the proposed method;

FIG. 14 shows an embodiment of an interconnect by an additional process step, e.g. heating for soldering/sintering) for the attachment of the side surfaces to produce a stacked laser arrangement according to the proposed method;

FIGS. 15A to 15C show a further embodiment of some process steps according to the proposed principle;

FIG. 16 shows a further design option for a stacked laser arrangement according to some aspects of the proposed principle;

FIG. 17 shows a cross-sectional view of a stacked laser arrangement with further aspects according to the proposed principle similar to the design of FIG. 16);

FIG. 18 shows a cross-sectional view of a stacked laser arrangement with further aspects according to the proposed principle similar to the embodiment of FIG. 16);

FIG. 19 is a perspective view of a stacked laser arrangement with some further aspects according to the proposed principle similar to the embodiment of FIG. 16);

FIG. 20 shows a top view of the stacked laser arrangement according to FIG. 19;

FIG. 21 is an enlarged view of the top view to explain further aspects;

FIG. 22 shows a further embodiment of a stacked laser arrangement according to some aspects of the proposed principle;

FIG. 23 shows a further embodiment of the idea of the invention;

FIG. 24 is a perspective view of a stacked laser arrangement with some further aspects similar to the embodiment of FIG. 22.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

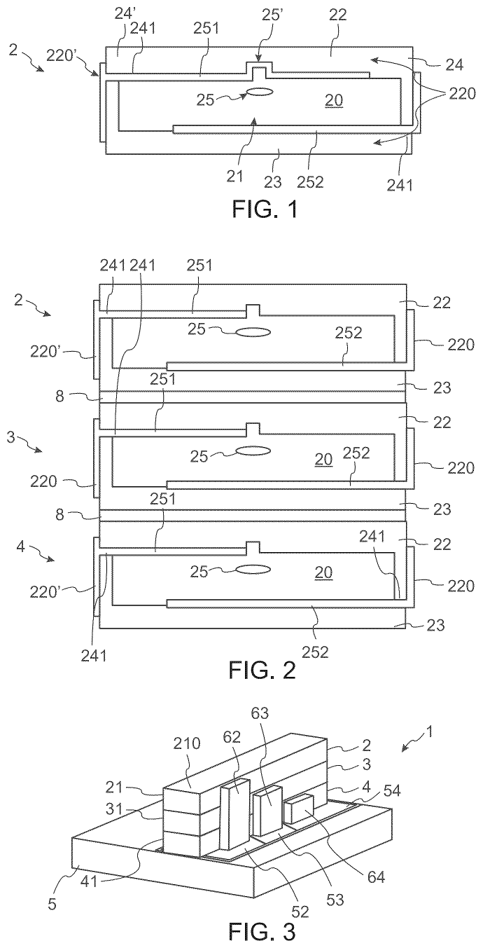

FIG. 1 shows a cross-section of a laser device according to the proposed principle as seen from the light-emitting surface. The laser device comprises a semiconductor body 20 in which an active zone 25 provided for generating light is formed. The zone is usually located under a so-called laser comb 25′ (ridge), the design of which deter-mines the resonance of the laser. The semiconductor body 20 has two differently doped areas, not shown here, which are electrically connected to the areas 251 and 252. Regions 251, 252 are designed, for example, as metallic layers and serve to supply charge carriers to the doped regions of the semiconductor body 20 and thus to the active zone 25.

The area 251 is arranged above the laser comb 25′, the area 252 below the active zone 25. The electrical areas are covered by a further dielectric layer 22 or 23, which form the first and second main sides. The thickness of the layers can be chosen differently or, in some embodiments, can be partially omitted. Similarly, the side surfaces 24 and 24′ are formed by an insulating material. In other words, the semiconductor body is substantially surrounded by a dielectric material which is at least partially located on the side surfaces.

Openings 241 are provided in this insulating material, which lead the electrical areas 251 and 252 to the outside and connect them to an electrical contact 220 and 220′ in the form of a metallic layer on the dielectric material of the side surfaces 24 and 24′. Thus, contacting of the laser device according to the invention does not take place along the main sides, i.e. against or in the direction of growth of the laser device, but along the side surfaces. This makes it possible to arrange contacting along the entire length of the resonator and at the same time to stack the laser devices on top of each other. The metallic layer can have different thicknesses or even different materials (e.g. a layer sequence or similar) and thus be particularly suitable for applying a batch or for bonding.

FIG. 2 shows an example of such an embodiment, in which the individual laser devices 2, 3 and 4 are connected to one another via a dielectric adhesive layer 8. Specifically, the first main side 22 of the laser device 4 is attached to the second main side 23 of the laser device 3 via the adhesive layer 8. The laser device 2 is applied to the main side 22 of the laser device 3 via the adhesive layer 8 and attached to the laser device 3. The widths of the respective laser devices are selected so that the side surfaces are flush with each other. The contacts 220 and 220′ are now attached to the side surfaces, which conduct the current to the respective active zones 25 via the openings 241 into the interior of the respective laser device.

The laser arrangement shown in FIG. 2 comprises three laser devices for generating light of different wavelengths in this design example. It is possible to optimize the design of the individual laser devices for each wavelength and still arrange them on top of each other. For example, in addition to the single ridge laser devices shown here, multi ridge laser devices can also be realized and stacked on top of each other. Furthermore, in this embodiment example, the laser devices are arranged in such a way that the laser combs point in the same direction, i.e. upwards in the embodiment example. In other words, the respective main side with the laser comb faces a main side of a neighboring laser device, which in turn faces away from the laser comb. This configuration can also be varied so that, for example, laser devices can be stacked comb to comb, i.e. in pairs.

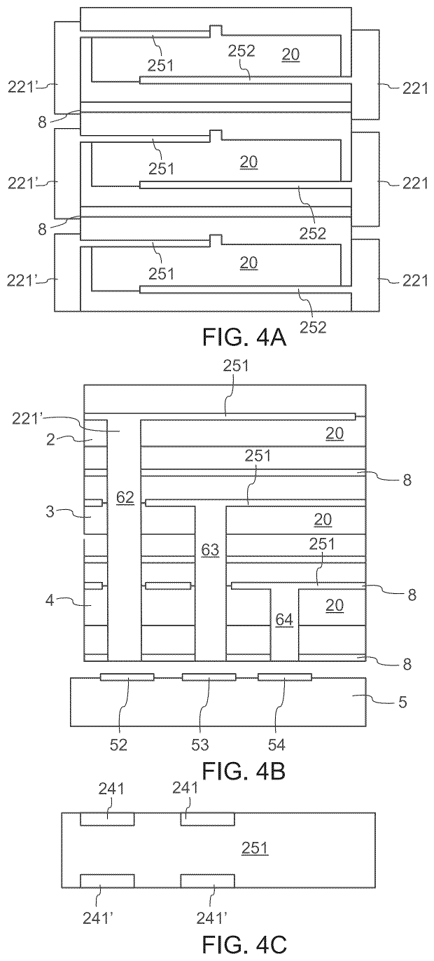

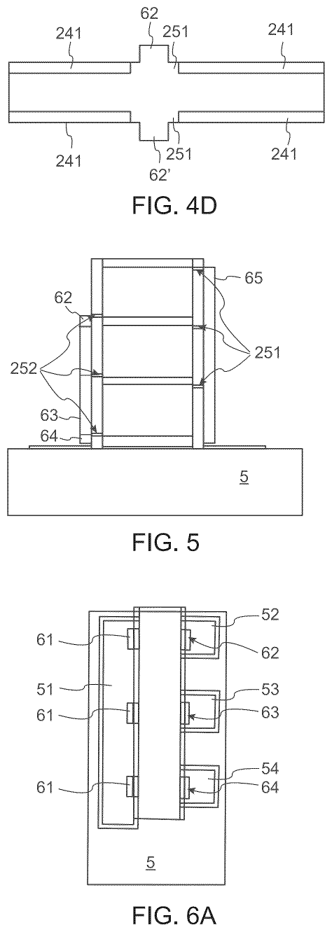

The design with the contacts along the side surfaces now makes it possible to attach the stacked laser arrangement to a carrier in different and therefore flexible ways. FIGS. 7 and 4A to 4D show various designs for this purpose.

FIG. 3 shows a stacked laser arrangement according to the proposed principle.

The stacked laser arrangement 1 comprises 3 laser devices, 2, 3 and 4, which are each designed as so-called edge-emitting lasers with a laser bar. The light-emitting surface lies on the edges 21, 31 and 41 facing the observer. The laser devices 2, 3 and 4 shown here are designed to generate and emit light of different wavelengths. Specifically, the laser device 2 is designed to generate and emit red laser light on the light-emitting surface 21, the laser arrangement 3 is designed to generate blue laser light and the laser arrangement 4 is designed to generate green laser light.

The individual laser devices 2, 3 and 4 are stacked on top of each other as shown. In particular, the device 4 is mounted with a first main side on a contact surface of a carrier 5. Its second main side is in turn arranged adjacent to the second laser device 3 and mechanically connected to it. The laser device 2 is attached to the second main side of the laser device 3 facing away from it. This results in the stacked arrangement of several laser devices shown in this and the further embodiments.

All 3 laser devices are designed in such a way that they have the same width so that the side surfaces of the respective laser devices are flush with each other. An end layer 210 is applied to the main side of the uppermost laser device 2 facing away from the carrier 5. In the present embodiment example, the width of the light-emitting surface 21, 31, 41 is significantly smaller than the length of the respective laser devices. Accordingly, the height of each laser device is also significantly smaller than the width of the light-emitting side or the length of the corresponding laser device. The resonance length of the respective device is also essentially determined by the length of the laser device.

For contacting the individual laser devices, metallic contact bars 62, 63 and 64 are now provided, which are electrically connected to contact surfaces 52, 53 and 54 on the upper side of the carrier 5. The contact bars 62, 63 and 64 lead along the side surfaces of the laser devices up to the respective contacting (not visible as they are covered by the bars). For this purpose, the side surface made of an insulating material is perforated at the corresponding point so that an electrical connection is created between the respective contact web and the active zone within the laser device. In detail, the contact web 62 running along the side surface thus contacts the laser device 2, the contact web 63 contacts the laser device 3 and the contact web 64 contacts the laser device 4. The respective contact web runs over the insulating material of the side surfaces of the respective other laser devices, so that a short circuit or undesired electrical contact with the other laser devices is avoided. The individual contact bars also end in the upper quarter of the respective side surface of the laser devices, as this is where the opening through the insulating material is located.

In this way, stacked laser arrangements with the same resonator length can be realized in a space-saving manner, with contact being made via contact bars along the side surfaces. This approach makes it possible to produce stacked laser arrangements as such in a separate manufacturing process and then to arrange and attach them to an appropriately prepared carrier.

FIGS. 4A to 4D show an embodiment of these laser arrangements in which the laser arrangement is placed in a horizontal configuration directly on a carrier and is electrically contacted with it. The illustration in FIG. 4A shows that the contacts of the side surface are designed as so-called web contacts, which are characterized by a greater width and thickness compared to a thinner metal layer as in the previous embodiments. In detail, the web contacts 221 for supplying charge carriers to the lower electrical region 252 extend not only over the side surface of the respective laser device, but also over a part of the adhesive layer 8 and an upper region of the insulating material of the following downstream laser device.

The web contacts 221′ for feeding charge carriers to the contact area 251 of the respective laser device, on the other hand, extend only over the side surface and a part of the adhesive layer 8. The web contacts 221 and 221′ are designed as elongate contact webs 62, 63 and 64, which extend over the side surfaces of the respective other laser devices as far as a lower area, where they are attached to the contact surfaces 52, 53 and 54.

A corresponding side view to explain this structure is shown in FIG. 4B. Here, the web 62 with its web contact 221 extends from the laser device 2 via the laser devices 3 and 4 to the contact element 52. The web 63 extends from the laser device 3 via the laser device 4 to the contact element 53 on the carrier 5; the contact web 64 extends only from the upper contact 251 of the laser device 4 to the contact surface 54 on the carrier 5.

A top view of the structure shown in FIG. 4B, FIG. 4C shows several recesses 65 of a laser device. The contact bars 63 and 62 extend in these recesses or on these recesses, so that metallization distances are realized on the side surfaces in order to avoid short circuits due to lateral electrical contacting of the bars. In this embodiment of FIG. 5C, the contacting plane 251 extends to the edge of the respective laser device.

In an alternative embodiment, shown in FIG. 4D, the metallic structure 251 is arranged within the laser device in such a way that a slight distance remains to the edge of the respective laser device, in particular to the side surface. The gap is created by a dielectric material that extends around the metallic layer. Only in the region of the later webs 62 or 62′ is the dielectric material perforated and the perforation through the insulating material of the side surface 241 filled with an electrically conductive material. In other words, the side surface can therefore be provided by a dielectric material which is perforated in places and filled with an electrically conductive material.

For contacting the inner metallic layer to the active zone, a breakthrough through the insulating electrical material, as for example in FIG. 4D, is therefore in this context equivalent to the representation in FIG. 4C, in which the electrically insulating material of the side surfaces 241 and 241′ is also removed at least in places.

FIG. 5 shows a further embodiment of the invention. In this illustration, the vertically offset aperture through the insulating material of the side surfaces for contacting the respective electrically conductive areas of the laser devices can be recognized particularly well. The apertures 251 and 252 are vertically offset relative to each other and extend through the insulating side wall or side surface. Depending on the design, it is possible to form the contacts as metallized layers or web contacts 62, 63 and 64 as well as a common web contact 65.

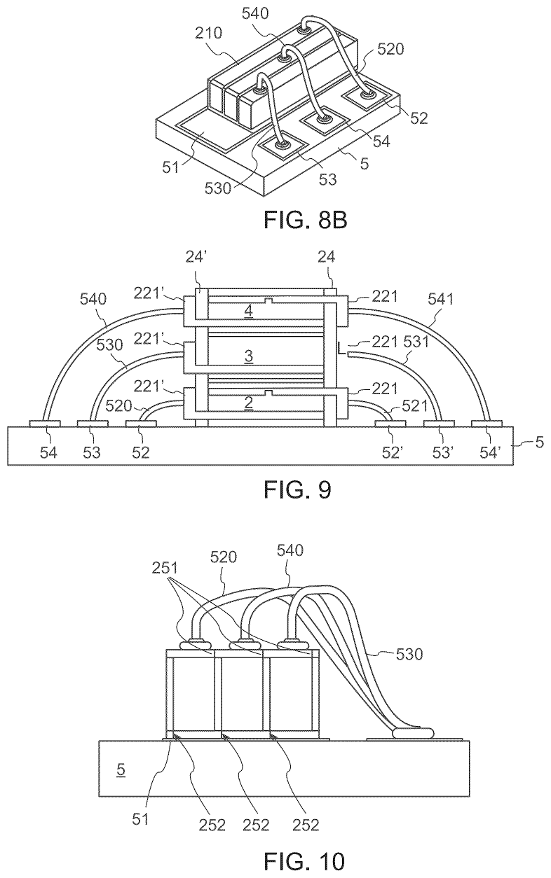

Alternatively, as can be seen in some other embodiments with reference to the figures, the laser arrangement can be placed rotated by 90° on the carrier 5 and on a common contacting plane 51. The conductive metallic layers on the side surfaces are electrically conductively connected to the apertures 252, so that the contact surface 51 on the upper side of the carrier forms a common contact for the individual laser devices of the laser arrangement. The averted side surfaces are guided to separately arranged contact areas on the surface via bonding wires 520, 530 and 540. In this respect, this design is also similar to the illustration in FIG. 8B.

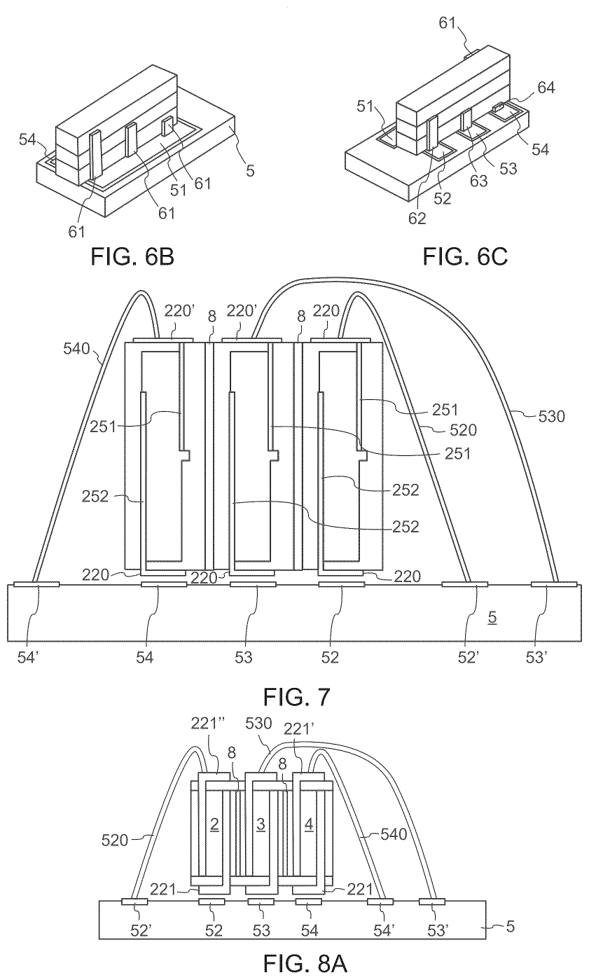

In FIG. 6A, the embodiments of FIG. 5 are shown rotated by 180° in plan view. A common contact 51 is connected to electrically conductive webs 61, each of which contacts the upper feedthroughs 251 as a common contact. On the other side of the embodiment, individual contact areas 52, 53 and 54 are provided on the upper side of the carrier 5, which are in conductive connection with the contact webs 62, 63 and 64. These each lead to the lower aperture of the laser devices, so that each of the laser devices is contacted on the one hand by a common contact and on the other hand by individual contacts and can therefore be controlled individually.

FIGS. 6B and 6C also show such a design in perspective view. FIG. 6B clearly shows that the differently shaped webs 61 lead from the common contact surface 51 to the upper through-hole plating in the laser device. The side walls of the laser devices are electrically insulated from the webs 61 so that the formation of a short circuit is avoided. As in other embodiments, the light-emitting surface is flush with the edge of the carrier 5. FIG. 6C shows the 180° rotated view of this design. The individual webs 62, 63 and 64 lead to the respective lower vias or openings through the side walls of the laser devices. In this embodiment, it can be seen that only the contact web 61 covers the side surface of the laser device to be contacted, while the second contact webs 62, 63 and 64 only cover—if at all—a partial area of the side surface, and the aperture is provided in the lower area of the side surface. Depending on the configuration, the type and also the position of the aperture can be changed in order to achieve suitable contacting of the differently doped layers of the semiconductor body and thus of the active zone. In this respect, the shapes and connections shown here in these embodiment examples are to be understood as merely exemplary. However, it is important to note that, in contrast to conventional technologies, the connections are not made from the main side, but from the side surface.

In FIG. 7, one of the laser arrays stacked in FIG. 2 is rotated by 90° and placed with its side surfaces on a carrier 5. In detail, the contacts 220 on the side surfaces are electrically conductively connected to corresponding contact areas 52, 53 and 54. The contacts 220′ on the respective other side face are connected to further contacts on the surface of the carrier 5 via bonding wires 520, 530 and 540. Due to this vertical arrangement, the fast axis of the respective emitted light profile is also rotated by 90° during operation and therefore runs essentially parallel to the carrier surface. With a suitable design of the light profile, the slow axis therefore does not exceed the width of the respective laser device, so that the stacked laser arrangement can be placed directly on the carrier and electrically contacted without any further submount as shown.

FIGS. 8A and 8B show a side view or perspective view of an embodiment similar to that shown in FIG. 7. Here too, bar contacts 221 and 221′ are arranged along the entire side surface of the respective laser devices 2, 3 or 4. The web contacts 221 can be placed directly on the contacts 52, 53 and 54 on the carrier 5 by rotating the stacked laser arrangement through 90°. The bar contacts 221′ are guided outwards onto the corresponding contact surfaces on the carrier 5 via bonding wires. This can also be seen in the perspective view shown in FIG. 6B. The advantage of such a design with contact surfaces 210 extending over the side surfaces is, on the one hand, a low specific resistance when supplying charge carriers to the respective active zone and, on the other hand, the greater flexibility of being able to design the bonding wires according to the desired design and arrangement of the contacts 52, 53 and 54 on the surface of the carrier. A metallic layer 51 on the carrier 5 forms a common contact to which the stacked laser arrangement with the side surfaces of the individual laser devices is applied.

FIG. 9 shows a further embodiment in which the stacked laser arrangement is arranged along its main sides on a carrier 5. In this embodiment, the laser device 2 is the laser device of the arrangement closest to the carrier 50. The web contacts 221 and 221′ are guided to the respective contact surfaces on the surface of the carrier 5 via respective bonding wires 520, 530 and 540 or 521, 531 and 541. Since the web contacts 221 and 221′ extend along the entire side surface of the respective laser devices, this design allows a flexible arrangement of the bonding wires over the entire length of the laser arrangement. This ensures that the bonding wires do not touch each other and thus cannot lead to a short circuit.

FIG. 10 shows a further embodiment of the invention. In these illustrations, the vertically offset aperture through the insulating material of the side surfaces for contacting the respective electrically conductive areas of the laser devices can be recognized particularly well. The apertures 251 and 252 are vertically offset relative to each other and extend through the insulating side wall or side surface.

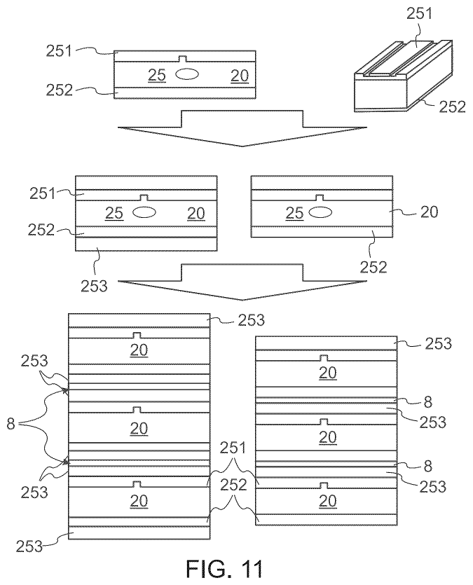

FIGS. 11 and 12 and 13 to 15 show various aspects of a manufacturing process for a stacked laser arrangement according to the proposed principle, in particular as shown in the preceding embodiments. FIG. 11 shows the first steps of such a processing method. In a first step of the manufacturing process, a laser structure is created by epitaxially producing, for example, differently doped semiconductor materials with an active zone in between. The resulting semiconductor body is shown in perspective view in the partial illustration on the right.

It comprises a substrate, an n-contact on the rear side and a p-contact on the top side. An additional laser comb is provided by a corresponding structure, simultaneously forming the active zone 25 and serving as a resonator for the laser device. In the left-hand section of the figure, the n-contact and p-contact are schematically represented by the metallic areas 251 and 252 respectively. This simplified representation serves to illustrate the essential aspects of the laser device, but is not to be understood as a geometrically or structurally precise design of the laser device. Alternative designs and manufacturing possibilities are known to the skilled person. However, it is essential that the electrically conductive areas 251 and 252 are designed up to the side surface of the semiconductor body 20, as shown in the left partial figure, so that the active zone can be contacted from above or below as well as from the side. In a subsequent step, the top or bottom side, i.e. the respective metallic contacting, is provided with a dielectric material. These form the two main sides of the laser device. In the right-hand embodiment of the manufacturing process, only the side facing the laser comb is covered with a dielectric material, while the lower side with the n-contact 252 remains free.

In a further process step in FIG. 11, the individual laser devices are stacked on top of each other. It is possible to separate the laser devices before stacking, but groups of laser devices can also be stacked on top of each other and processed further. In particular, so-called wafer stacking is possible by aligning the individual laser devices with each other at wafer level and then stacking the wafers on top of each other. In both embodiments, the stacking is carried out by an additional adhesive layer shown here, which is arranged between the dielectric material in the left-hand partial image or between the dielectric material and the n-contact in the right-hand partial image. The adhesive layer 8 is also dielectric, so that sufficient electrical insulation is provided together with the material of the main side of the underlying laser arrangement. The advantage of the right-hand design is a significantly smaller vertical structure, as the electrically insulating underside of each of the laser devices can be saved. In addition, this design allows the n-contact of the lowest laser device to be placed directly on a corresponding contact area of a carrier.

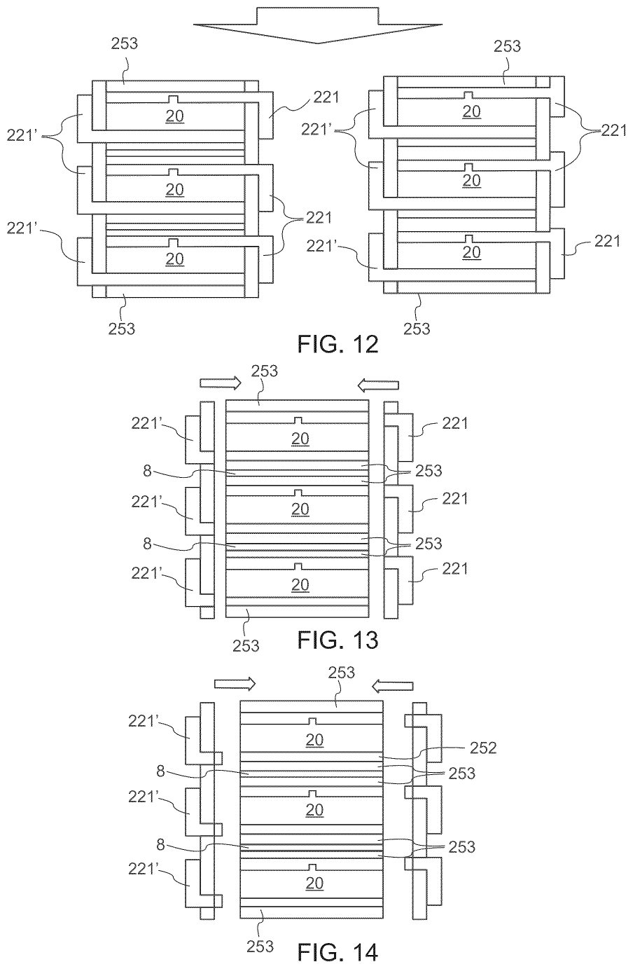

In a further process step in FIG. 12, the side surfaces of the stacked laser arrangements are now provided with a dielectric material by arranging openings. These openings 251 and 252 are filled with a conductive material so that they contact the conductive areas 251 and 252 that are guided to the edge. In turn, metallic layers 220 or 220′ are applied to the side surface, which are in contact with the electrically conductive material in the openings. In this way, contact is made from the side surfaces of the laser arrangement.

In the right-hand partial figure of FIG. 12, contacting is carried out in the same way. Only for the lowest laser device is the actual side contacting superfluous to a certain extent, as the conductive n-contact is already exposed and contacting can also be made directly via this.

The method of this final manufacturing step, in particular the creation of dielectric side surfaces with corresponding contacting and openings at the level of the electrical areas, is flexible and can be carried out in various ways.

FIGS. 13 and 14 show an embodiment example in which the side surfaces are produced separately and independently of the stacked laser arrangement. In the embodiment example shown in FIG. 13, a dielectric surface is provided which has several openings filled with metal. The spacing, shape and nature of these apertures is such that, when aligned, they correspond to the electrical areas 251 and 252 of the stacked laser arrangements. The side surfaces can be designed to be self-adhesive so that they adhere to the sides of the laser device after alignment and thus make contact with the electrical areas 251 and 252. With a corresponding further temperature and pressure step, the electrical areas can be securely contacted with the material filled in the openings. For this purpose, the material present in the openings can be a solder or another metallic material with a low melting point, for example.

In an alternative embodiment, shown in FIG. 14, it is also possible to provide an additional thin solder material on the inside of the side surfaces in the area of the apertures. The additional material makes it possible to provide an intimate connection between the material of the apertures and the areas 251 and 252 of the stacked laser arrangement in a further temperature step.

The advantage of this design is the separate and thus distinct production of the later side surfaces from the stacked laser arrangement, whereby an independent process optimization of both manufacturing processes is achieved. Suitable epitaxial measures can be used to increase the surface area of the electrically conductive areas in the area of the side edges of the laser devices, thus enabling a greater tolerance for the alignment of the side surfaces to the side edge of the laser devices.

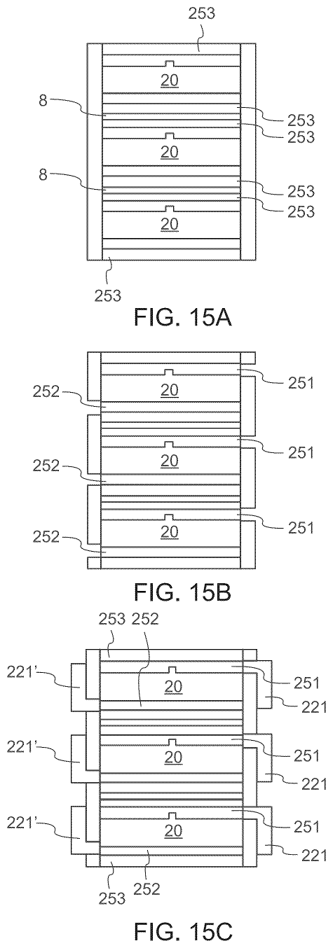

FIGS. 15A to 15C show another embodiment for producing side surfaces with contacting according to the proposed principle.

In this case, the stacked laser arrangements are surrounded by a dielectric material. In particular, the side edges are coated with a dielectric material. The dielectric material can then be structured and several openings created in it. The position of the openings is selected in such a way that the edges of the areas 251 and 252 are exposed on the different side surfaces. In the present embodiment example, the areas 251 are exposed through apertures in the right-hand side surface, while the electrical areas 252 of the laser devices are exposed through apertures in the left-hand side surface. Of course, it is also possible in this context to provide both contacts on one side surface or alternately depending on the requirements and application. The apertures can be made larger than the thickness of the contacting areas 251, 252 within the laser device in order to ensure reliable contact with a conductive material that is subsequently filled. In a further final step, a material is filled into the apertures and an electrically conductive layer is applied to the outside of the side surfaces.

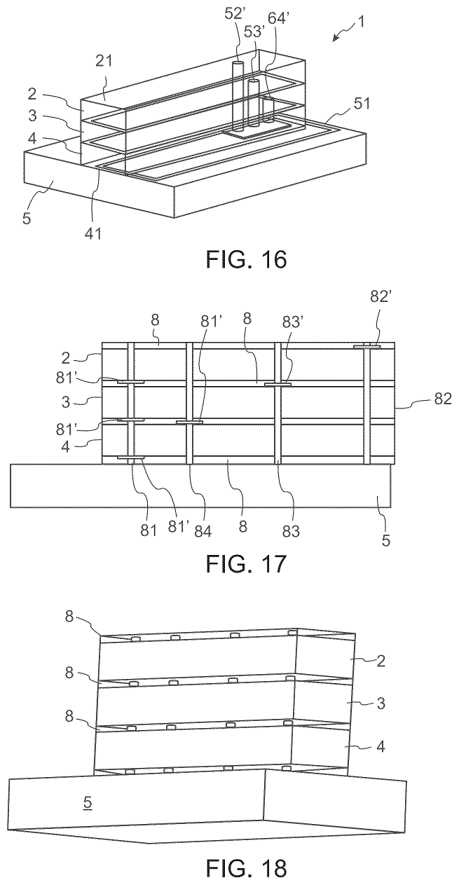

FIG. 16 shows a further supplementary embodiment in this respect, which realizes various aspects of the proposed principle in a different way. In this embodiment, instead of contact bars, 62, 63 and 64, corresponding apertures or via are provided through the rear region of the respective laser devices. As with the contact lands in a similar manner, each via comprises an insulating material at its surrounding edge into which a conductive component is inserted. The contact via 62′ thus breaks through the laser devices 4 and 3 in an insulated manner and makes electrical contact with the active zone of the laser device 2. Accordingly, the via 63′ contacts the laser device 3, the last contact via 64′ only extends through a part of the material of the laser device 4 and contacts an electrically conductive layer to the active zone there.

In this context, it is also conceivable that the individual contact via or apertures not only contact a layer in an individual laser device, but also serve as a common contact for a laser device and the laser device stacked on top of it. For example, the contact aperture 64′ can contact both an electrically conductive area to the active zone of the laser device 4 and a further electrically conductive area to the active zone of the laser device 3 as a common contact. Contact is also made between the electrically conductive areas to the respective active zone of the laser devices 3 and 2 with the contact via 63′. The laser device 4 also lies on a contact surface 51 of the carrier 5. Electrical activation is achieved, for example, by a current via the contact surface 51 and the common contact aperture 64′. In the same way, the laser devices 2 and 3 can also be controlled individually, i.e. separately or together.

FIG. 17 shows another embodiment of a stacked laser arrangement in a cross-sectional view. In this embodiment, the individual laser devices 2, 3 and 4 have the same length and are stacked on top of each other as in the other embodiments. The lowest laser device 4 is also attached to the carrier 5. In the embodiment example in FIGS. 18 and 19, also shown in a perspective view, the individual laser devices are contacted via openings arranged within the laser devices. The apertures comprise a dielectric material at the edge of each aperture and a metallic core on the inside. The individual openings thus create an electrical feed-through from the underside of each laser device to the corresponding upper side

FIG. 17 shows such feedthroughs 82, 83, 84 and 81. The feedthrough 81 is now designed in such a way that it contacts a corresponding metallic layer 81′ on the underside of each laser device and thus connects the lower main side of the laser devices 2, 3 and 4 to the contact surface 51 on the carrier. The openings through the individual laser devices are designed in such a way that the electrically conductive material present therein enables a continuous electrical connection between the lowest contact area on the carrier 5 and the uppermost layer 81 for the laser device 2.

The vias 82, 83 and 84, on the other hand, are designed in such a way that they only contact an upper main side of each individual laser device. Specifically, the through-holes 82 lead from the carrier 5 through the first and second laser devices 4 and 3 and the third laser device 2. On the upper main side, the laser device 2 now comprises a contact lug 82′, which forms the contact for the laser device on the upper main side. In the same way, the through-hole plating 83 is designed so that it makes electrical contact with the contact area 83′ on the main side of the laser device 3. This contact area is also separated from the lower main side of the laser device 2 by an electrical insulation 8. The third aperture 84 leads from the carrier 5 through the material of the laser device 4 to the contact area 34′, which contacts the upper side of the laser device 4.

In the embodiment example shown here in FIGS. 17, 18 and 19, the individual apertures are designed in such a way that they each extend completely through the laser devices 2, 3 and 4. The contact lugs 82′, 83′ and 84′ are used for contacting the corresponding laser device and are separated from the lower main side of the following laser device by an insulating intermediate layer 8. Only the feed-through 81 is designed as a common contact and connects the respective lower sides of the laser devices with the contact on the carrier 5. This design makes it possible to stack the laser devices 2, 3 and 4 on top of each other in any way and still be able to control each one individually.

FIGS. 18 and 19 show a perspective view of the stacked laser arrangement according to the proposed principle. FIG. 19 clearly shows the feedthroughs arranged within a certain area of each laser device. A conductive intermediate area is also provided, which runs through the insulation layer 8 and thus electrically connects the feedthroughs to each other. The individual contact lugs, which lead to the underside of the respective laser devices, can be seen on the underside.

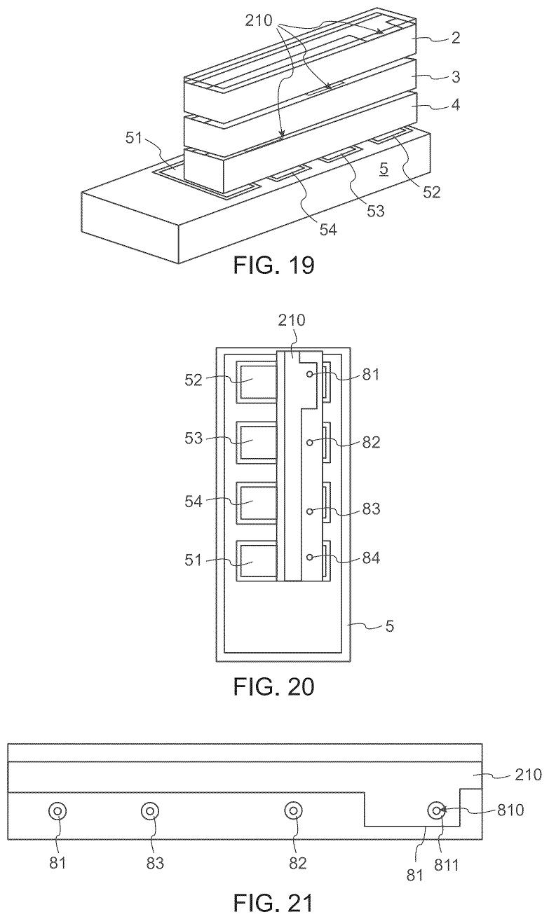

FIG. 19 shows a perspective view of the carrier. The individual contact areas 51, 52, 53 and 54 are designed on this. The contact area 50 again forms the common contact area for supplying a common potential to the individual laser devices. The other contact areas 52, 53 and 54 are connected to the metal through-hole plating. The current distribution layer 210 is also shown on the top of the laser device 2. This is electrically conductively connected to the via 81 and then runs along the side surface over the top of the laser device 2. In the same way, there is also a current distribution layer 210 on the top of the laser device 3, although this connects the via 82 as shown in FIG. 19. FIG. 20 shows the top view in this respect, from which the various feedthroughs 81, 82, 83 and 84 are visible. Not every one of these feedthroughs is also connected.

The current distribution layer on the uppermost laser device 2 is connected to the through-hole plating 81. In this way, different lasers of different colors can be stacked on top of each other and controlled separately. Laser devices of the same color can have the same design so that they can be controlled together through corresponding feedthroughs.

The openings are shown again in detail in FIG. 21. Each aperture is circular in shape and comprises an insulating edge 811. The edge consists of a dielectric material so that a short circuit in the feedthroughs is avoided. The core of each aperture comprises a metal 810, which fills the aperture insulated from the respective laser device. The current distribution layer 210, which is arranged around the respective aperture and connects the electrical core, is provided for contacting the laser device by means of this aperture

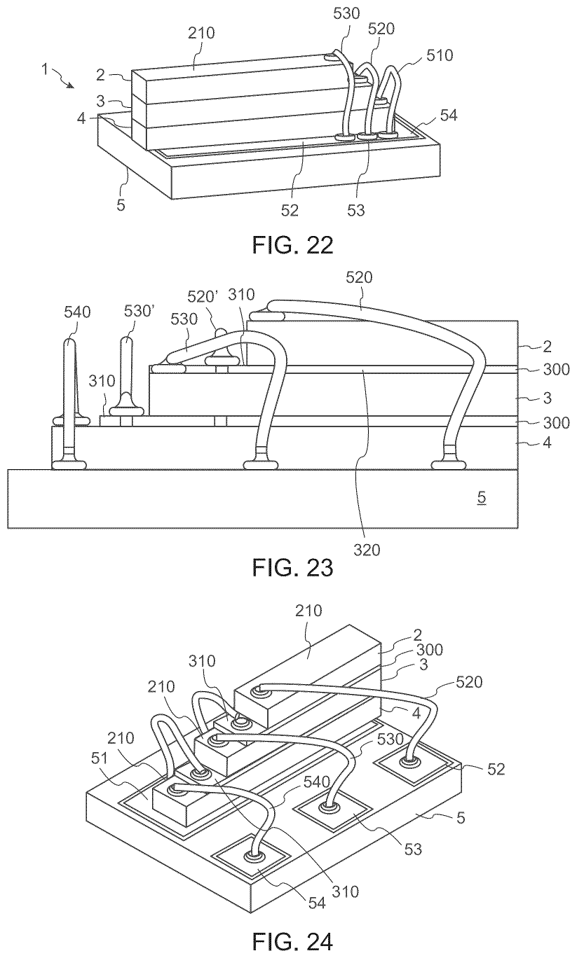

Another, slightly simpler embodiment is shown in FIG. 22. In contrast to the previous embodiments, the laser devices 2, 3 and 4 do not have the same resonator length, but are chosen differently. Here too, the laser devices are stacked on top of each other along their main sides and fastened together, whereby the side surfaces are also flush with each other. In contrast to the previous embodiments, however, bonding wires 510, 520 and 530 are provided here, which contact the main sides located at the top in an area facing away from the light-emitting surface. The bonding wires are guided to corresponding contacts 52, 53, 54 on the carrier 5. As shown in a similar way in FIG. 16, the individual contacts or the bonding wires 510 and 520 can also be used here for joint contacting of the laser devices 3 and 4 or 2 and 3.

FIG. 23 shows a further embodiment of a stacked laser arrangement according to some aspects of the proposed principle. In this laser arrangement, the individual laser devices are designed with different resonator lengths and are stacked on top of each other in such a way that the laser device with the longest resonator length faces the carrier 50. The individual laser devices 2, 3 and 4 are designed in such a way that a first contact surface is arranged on the underside of each laser device and a second contact surface is arranged on its corresponding upper side. The second contact surface is provided on the upper side at the end of the respective laser device facing away from the light-emitting side. As shown in the embodiment of FIG. 23, the contact surfaces on the upper side of the respective laser device 234 are guided via bonding wires to corresponding contact areas on the carrier 5.

FIG. 24 shows a perspective embodiment in which the contact surfaces 52, 53 and 54 on the carrier 5 are shown. In detail, a bonding wire 520 leads via a contact surface 52 to the upper side 210 of the laser device 2. The upper side has a metallization layer 210 substantially completely covering the main side, so that the bonding wire 520 can be applied flexibly over the entire main side of the laser device 2.

The bonding wire 530 leads from the contact surface 53 on the carrier 5 to a contact area 210 of the laser device 3 at the end facing away from the light exit side. Accordingly, the bonding wire 540 contacts the contact surface 54 on the carrier with a contact area of the laser device 4, also at the end facing away from the light exit side.

Referring again to FIG. 23, the stacked laser arrangement shown here also comprises a plurality of insulating plates 300 between a top surface of a laser device and the bottom surface of the laser device stacked thereon. The platelet or also the insulating layer 300 consists of an insulating material and has a metallic layer 210 on the side facing a lower side of the laser device. The metallic layer 210 contacts the contact located on the lower main side of the respective laser device. In the embodiment example of FIG. 23, two insulating layers 300 are shown, namely between the laser device 4 and 3 and the laser device 3 and 2. The insulating layer 300 comprises a ceramic or other insulating material and a metallization layer 310 on its surface. In the embodiment example, this metallization layer extends over the entire upper side of the insulation layer 300 and thus makes contact with the contact of the laser devices 3 and 2 located on the lower main side. In FIG. 24, the lower contact of the laser device 4 is connected to the electrically conductive contact surface 51 on the carrier 5.

Due to the different resonator lengths of the laser devices 2 and 3, an area of the metallic layer 310 of the respective insulation layers 300 is exposed. This is connected to the contact surface 51 on the carrier via a bonding wire. The metallization layers 310 of the individual insulation layers 300 are thus at the same potential as the electrically conductive contact surface 51 of the carrier. In this respect, each contact on the lower main side of the laser devices is at the same potential.

With this design, laser devices can also be stacked on top of each other which, on the one hand, have a different resonance length and, on the other hand, whose contacts are arranged on the opposite main sides. The additional insulating layer 300 thus enables the contact of the lower main side to make contact with the metallization applied to the surface while at the same time providing insulation between the individual laser devices. Depending on the embodiment, it is also possible that the insulation layers allow a certain amount of heat transport and can be used to cool the laser devices.

In a further embodiment not shown here, the metallic contact webs also shown in the preceding embodiment examples can be formed along the side surfaces, which are in contact with the exposed contact areas on the upper main side of the respective laser device or with the metallization layer 310 of the individual insulation layers. This makes it possible to stack laser devices whose contacts are located on the opposite main sides on top of each other and still contact them via the webs running across the side surface shown in the previous embodiment examples.

The embodiments shown here in FIGS. 3, 16 and 22, as well as their modifications in the other figures, show stacked laser arrangements that can be arranged on a carrier in a particularly space-saving manner. The stacked laser arrangements can be produced separately, tested and prepared for later use.

1. A stacked laser arrangement, comprising:
a first laser device with a light-emitting side and a semiconductor body forming a resonator with an active zone and with two main sides and side surfaces arranged substantially perpendicularly thereto, the side surfaces comprising an insulating material; and
at least one second laser device having a light-emitting side and a semiconductor body forming a resonator and having an active zone and having two main sides and side faces arranged substantially perpendicularly thereto, the side faces comprising an insulating material; wherein
the light-emitting sides of the first laser device and at least one second laser device point in the same direction and the at least one second laser device is arranged on one of the main sides of the first laser device; and
wherein electrical contact is made to the active zone of the first and at least one second laser device via at least one of their respective side surfaces, in that the insulating material is perforated in places.

2. The stacked laser arrangement according to claim 1, wherein the first and/or the at least one second laser device each comprises a first electrical contact on a first side surface and a second electrical contact on a second side surface; or wherein the first and/or the at least one second laser device each comprises a first and second electrical contact on a first side surface, wherein the first and second electrical contacts are laterally spaced apart.

3. The stacked laser arrangement according to claim 1 wherein a metallic layer is arranged on the side surfaces, each forming a contact surface; wherein optionally the metallic layer is extended over at least 50% of a length of the side surface.

4. The stacked laser arrangement according to claim 1, wherein, in view of the light emitting side and with respect to one of the main sides, an opening through the insulating material on one side surface is vertically offset from an opening through the insulating material on the other side surface.

5. The stacked laser arrangement according to claim 1, wherein at least one of the mutually facing main sides of the first and at least one second main side comprises an electrically insulating material.

6. The stacked laser arrangement according to claim 1, in which the contacting takes place via a conductive web extending at least partially along the side surface of the respective laser device, wherein the conductive web optionally extends partially over a side surface of the respective other laser device.

7. The stacked laser arrangement according to claim 6, wherein the conductive web on a side surface of the first laser device and the conductive web on a side surface of the at least one second laser device are formed as a common metallic layer.

8. The stacked laser arrangement according to claim 1, wherein an adhesive layer is arranged between the first laser device and the at least one second laser device.

9. The stacked laser arrangement according to claim 1, wherein the first laser device has a resonator length which differs from a resonator length of the least one second laser device.

10. The stacked laser arrangement according to claim 1, further comprising:
a carrier with a number of contact surfaces, in particular contact surfaces arranged in a row; wherein
the first and at least one second laser device is arranged in such a way that the electrical contacting of the side surface of at least one of the first and at least one second laser device is arranged on the contact surfaces.

11. The stacked laser arrangement according to claim 1, wherein a contact on the side surface facing away from the contact surfaces is guided to a contact surface on the carrier via a bonding wire connection.

12. The stacked laser arrangement according to claim 1, further comprising:
a carrier with a number of contact surfaces, in particular contact surfaces arranged in a row; wherein
a main side of the first or at least one second laser device is arranged facing the carrier and a conductive web along the side surface of the first or at least one second laser device is electrically conductively connected to one of the contact surfaces.

13. The stacked laser arrangement according to claim 1, further comprising:
a carrier with a number of contact surfaces, in particular contact surfaces arranged in a row; wherein
a main side of the first or at least one second laser device is arranged facing the carrier and a contact surface on one of the side surfaces of the first or at least one second laser device is electrically conductively connected to one of the contact surfaces via a bonding wire.

14. The stacked laser arrangement according to claim 12, wherein the contact surface on the other of the side surfaces of the first or at least one second laser device is electrically conductively connected to one of the contact surfaces via a bonding wire.

15. A method of producing a stacked laser arrangement comprising the steps of:
providing a first laser device with a light-emitting side and a semiconductor body forming a resonator with an active zone and with two main sides and side surfaces arranged substantially perpendicularly thereto; wherein the side surfaces comprise at least one electrically conductive region which electrically contacts the active zone;
providing at least one second laser device with a light-emitting side and a semiconductor body forming a resonator with an active zone and with two main sides and side surfaces arranged substantially perpendicularly thereto; wherein the side surfaces comprise at least one electrically conductive region which electrically contacts the active zone;
mutually aligned attaching of a main side of the at least one second laser device to a main side of the first laser device; and
producing an electrical contact on at least one of the electrically conductive regions of the first and at least one second laser device via at least one of their respective side surfaces, an insulating material which is perforated in the region of the contact being applied to the side surfaces.

16. The method according to claim 15, wherein mutually aligned attaching comprises fastening by an electrically insulating material, in particular an adhesive.

17. The method according to claim 15, wherein producing an electrical contacting comprises:
applying an electrically insulating layer on the side surfaces;
structuring the electrically insulating layer;
creating a breach in the electrically insulating layer to expose the at least one electrically conductive region;
filling of an electrically conductive material in the opening for contacting the electrically conductive area; and
forming an electrical contact on the side surface.

18. The method of claim 17, wherein forming an electrical contact comprises forming an electrically conductive ridge optionally extending along the side surface of an adjacent laser device.

19. The method according to claim 15, wherein the step of generating an electrical contacting comprises:
forming a layer sequence with an insulating material comprising one or more openings which are filled with an electrically conductive material; and
applying the layer sequence to the side surfaces of the first and at least one second laser device.
